(19) United States
(12) Patent Application Publication
(10) Pub. No.: US 2005/0218929 A1
(43) Pub. Date: Oct. 6, 2005

(54) Field programmable gate array logic cell and its derivatives

(76) Inventors: Man Wang, Sunnyvale, CA (US); Jack Z. Peng, San Jose, CA (US)

Correspondence Address: PERKINS COIE LLP;PATENT-SEA, P.O. BOX 1247, SEATTLE, WA, 98111-1247, US

(21) Appl. No.: 10/883,901

(22) Filed: Jul. 2, 2004

Related U.S. Application Data
(60) Provisional application No. 60/558,949, filed on Apr. 2, 2004.

(51) Int. Cl. H03K 19/177

(52) U.S. Cl. 326/41

(57) ABSTRACT

The present invention relates to the general area of the Field Programmable Gate Arrays, and, in particular to the architecture and the structure of the building blocks of the Field Programmable Gate Arrays. The proposed logic cells offer, among other advantages, by-pass and feedback paths, fewer transistors, no need for dedicated carry logic or multiple registers, 3-input instead of 4-input look-up tables, easy implementation of up to 4-input logic functions, and multiplication.

### CROSS REFERENCE TO RELATED APPLICATION(S)

This application claims the benefit of provisional U.S. Patent Application No. 60/558,949, filed Apr. 2, 2004, which is hereby incorporated by reference in its entirety.

### TECHNICAL FIELD

This invention relates to the field of Field Programmable Gate Arrays (FPGAs). In particular it relates to the architecture of FPGA building blocks.

### BACKGROUND

A digital logic circuit, generally formed as a cascade of separate logic functions, is a circuit that produces a digital output as a result of some logical operation on its digital inputs. Digital logic circuits are typically implemented on various types of integrated semiconductor chips. One widely known type of integrated chip is the Application Specific Integrated Circuit (ASIC), which is a custom-made integrated chip. Each ASIC is manufactured to implement a specific digital logic circuit.

Programmable chips are another type of integrated chips, but differ from ASICs because of their ability to implement any number of different complex digital logic circuits by configuring the underlying integrated chip. The programmable integrated chips are less costly than ASICs because a large number of similar integrated chips may be manufactured from a single design, which can later be configured to implement a wide variety of digital logic circuits. For this reason the cost of design and manufacturing is distributed over a large number of integrated chips.

FPGA is one type of programmable integrated chips. The FPGA can either be permanently programmed by the user, such as in the U.S. Pat. No. 4,758,745 by El Gamal, et al., or can be temporarily programmed by the user, described in the U.S. Pat. No. 4,870,302, by Freeman.

Typically an FPGA consists of an array of modularized logic cells and interconnection resources. It is an array of uncommitted gates with uncommitted wiring channels. Each logic cell can be programmed to implement a particular logic function. Various digital circuits may be implemented to execute desired functions by programming a number of logic blocks and interconnecting them using interconnection resources.

In other words, to implement a particular circuit function, the circuit is mapped into the array and the wiring channels and appropriate connections are programmed to implement the necessary wiring connections that form the circuit function. A gate array circuit can be programmed to implement virtually any set of functions.

Of utmost importance in designing an FPGA is the topology of the logic cells and the interconnection resources since different FPGA architecture provides different performance characteristics. Also, the programming of a gate array and the mapping of a desired functionality onto it depend upon the topology of the gate array. If the cells of the gate array are high level blocks, such as counters, parity generators, and the like, then the amount of programming required is limited to the interconnections among these large- or coarse-grain cells.

If, on the other hand, the cells of the gate array are low level blocks, such as gates, latches, and the like, then the amount of programming is significantly higher, because these smaller, or fine-grain, cells need to be interconnected to effect the higher level functions. In some designs the use of the fine-grain cells results in higher circuit densities because the desired functions can be implemented more efficiently with small low-level cells rather than with larger high-level cells whose high level functionality is useless in the particular circumstances.

A highly complex logic cell may be able to perform a large number of complex operations but if a relatively simple operation is desired much of the functionality and semiconductor real estate will be wasted. At the same time, a logic cell consisting of basic logic gates requires extensive wiring to perform sophisticated operations. In other words, some complex designs cannot be efficiently embodied in a fine-grain gate array, because the amount of interconnection required among the low-level cells exceed the capacity of the gate array. Various architectures have been proposed to optimize the tradeoffs among circuit building blocks, routing efficiency, performance limits, and the like. There is a need for logic cells that optimize flexibility and functionality of the FPGAs.

### BRIEF DESCRIPTION OF THE DRAWINGS

The foregoing aspects and many of the attendant advantages of the invention will become more readily appreciated as the same become better understood by reference to the following detailed description, when taken in conjunction with the accompanying drawings, wherein:

FIGS. 1-3 are schematic circuit diagrams of FPGA logic cells in accordance with the prior art.

FIG. 4 is a schematic circuit diagram of a 4-input 2-output logic cell in accordance with an embodiment of the present invention.

FIG. 5 is a schematic circuit diagram of a 5-input 2-output logic cell in accordance with an embodiment of the present invention.

FIG. 6 is a schematic circuit diagram of a 6-input 2-output logic cell in accordance with an embodiment of the present invention.

FIG. 7 is a schematic circuit diagram of a 7-input 2-output logic cell in accordance with an embodiment of the present invention.

FIG. 8 is a schematic circuit diagram of a 5-input 2-output logic cell with a dedicated AND gate to facilitate multiplication in accordance with an embodiment of the present invention.

### DETAILED DESCRIPTION

The present invention relates to the general area of Field Programmable Gate Arrays. In particular it relates to the architecture of the logic cells that are the building blocks of the Field Programmable Gate Arrays and the necessary interconnections to support their functionality. In the detailed description provided below, several different embodiments of a logic cell are disclosed. A single proposed logic cell offers, among other advantages, easy implementation of any logic function with up to four inputs; implementation of two parallel or series independent 2- and 3-input look-up tables (LUT2 or LUT3, respectively); or implementation of a 4-input look-up table (LUT4). It can also implement a 1-bit full adder or accumulator, without the need for dedicated carry logic, or can implement multiplication with the addition of a 2-input AND gate.

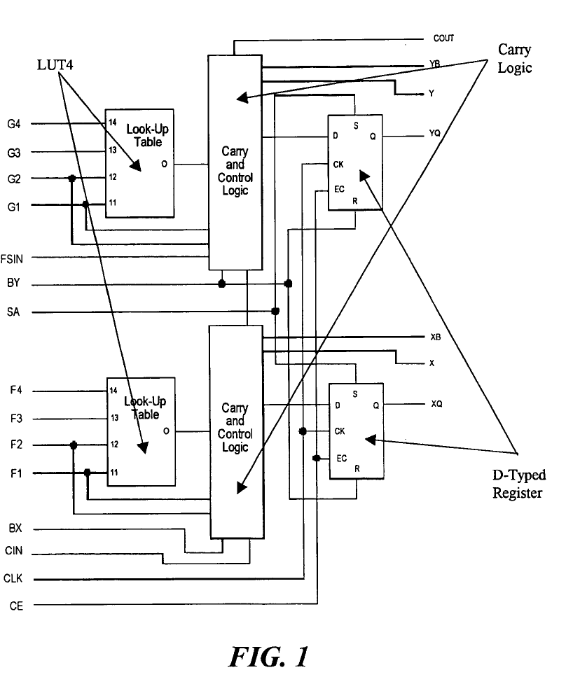

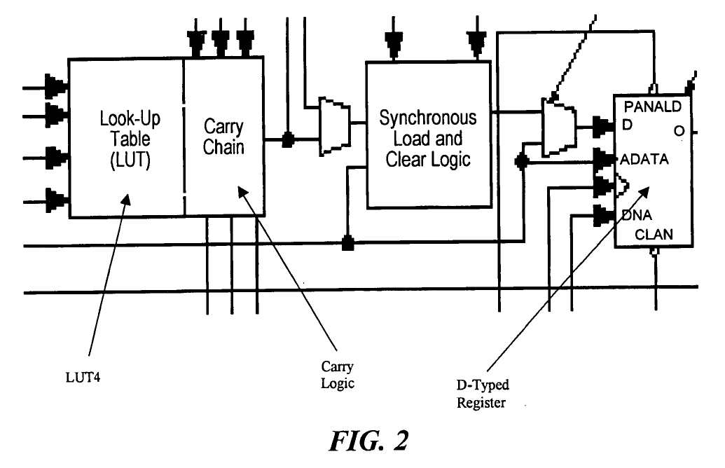

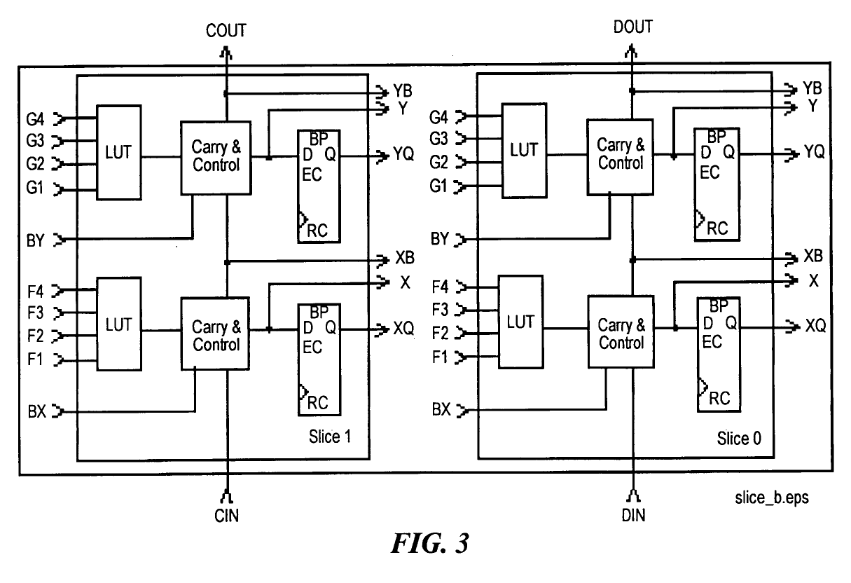

At the core of the proposed logic cells is a 3-input look-up table. These logic cells are further comprised of a plurality of multiplexers, a register, and programmable switches. The logic function of each logic cell is determined by the unique interconnection of these basic elements and the settings of the switches. On the other hand the logic cells of the prior art require 4-input look-up tables, dedicated carry logic, and multiple registers, which make them more complicated than the proposed logic cells while performing the same or fewer functions. FIGS. 1, 2, and 3 are schematic circuit diagrams of FPGA logic cells in accordance with the prior art and the presently available commercial FPGAs.

In the following description, several specific details are presented to provide a thorough understanding of the embodiments of the invention. One skilled in the relevant art will recognize, however, that the invention can be practiced without one or more of the specific details, or in combination with or with other components, etc. In other instances, well-known implementations or operations are not shown or described in detail to avoid obscuring aspects of various embodiments of the invention.

Reference throughout the specification to “one embodiment” or “an embodiment” means that a particular feature, structure, implementation, or characteristic described in connection with the embodiment is included in at least one embodiment of the present invention. Thus, uses of the phrases “in one embodiment” or “in an embodiment” in various places throughout the specification are not necessarily all referring to the same embodiment. Furthermore, the particular features, structures, implementation, or characteristics may be combined in any suitable manner in one or more embodiments.

Each of the proposed logic cell embodiments comprises two LUT3, a 2×1 standard multiplexer, a D flip-flop, five hard-wired multiplexers, and two pass-gate switches. The data enters the cell through inputs IP1 to IP7 and some are shared between the two LUT3s. The combination of the two LUT3s and a 2×1 multiplexer can implement a LUT4. They can also implement two LUT3, two LUT2, or one LUT2 and one LUT3, which can separately operate in parallel or in series. The outputs of the logic cells are available in both, the registered and the non-registered, forms. The output of a LUT2, a LUT3, or a LUT4 may be directed to either of the two outputs, OP1 and OP2, of the logic cell.

The by-pass switches in different embodiments of the proposed logic cells, provide feedback paths from the outputs of the cell to its inputs; enabling the cell to act as an accumulator or an AOI (And-Or-Inverter), or to simply by-pass the inputs to the output. A D flip-flop is shared among the two LUT3s of each logic cell. These registers make it possible for the logic cells to act as 1-bit full-adders, or accumulators, without the need for dedicated carry logic. These registers may also be used to form a register chain. The addition of a 2-input AND gate to a logic cell further enables the cell to perform multiplication.

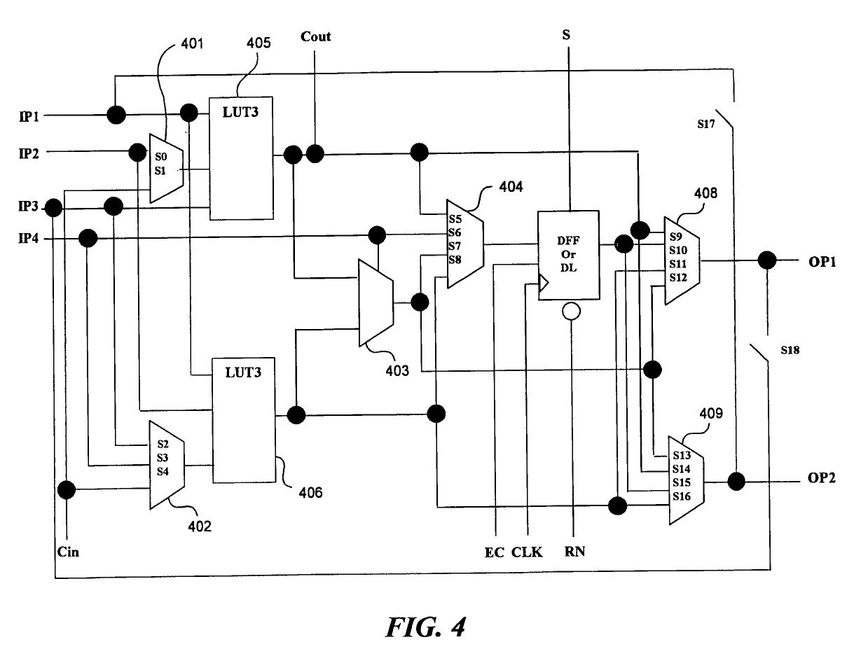

FIG. 4 is a schematic circuit diagram of a 4-input 2-output logic cell in accordance with an embodiment of the present invention. The LUT3 based proposed logic cell of FIG. 4 can implement any logic function of up to four inputs, or two independent LUT2 in parallel or in series as And-Or-Inverter/Or-And-Inverter (AOI/OAI). This logic cell can also implement a 1-bit adder or an accumulator without the need for dedicated carry logic. The register that is shared between the two LUT3s, can be separately used to form a register chain. As illustrated in FIG. 4, the proposed logic cell has feedback and by-pass paths. The proposed logic cell of FIG. 4 can further implement a LUT4, two LUT3, two LUT2, or one LUT2 and one LUT3, which can separately operate in parallel. Both, the registered and the non-registered, forms of the outputs of the look-up tables are available.

In the following paragraphs, the circuit of FIG. 4 is used as an example to demonstrate how any of the proposed logic cells may be programmed to implement an above-mentioned function. Based on these examples a person of ordinary skill in the relevant art will be able to program and configure such circuits to perform a desired function mentioned herein.

Each 3-input look-up table has 23 memory bits. The two of them together are capable of addressing 2(2³) or 2⁴ data bits, which is the same as the number of possible combinations of a 4-input logic gate. Therefor, to use the logic cell of FIG. 4 as a 4-input logic gate, where IP1 to IP4 are the inputs to the logic gate, multiplexer 401 should be hard-wired to route S0 and multiplexer 402 should be hard-wired to route S2 to their outputs (hereinafter will be referred to as setting S0 or setting S1). In this way IP1, IP2, and IP3 are the inputs of both LUT3s, and IP4 can be utilized to choose between the two LUT3 outputs, by controlling multiplexer 403. With this arrangement, the desired outcomes of all the logic combinations in which IP4=0 must be stored in one LUT3 and the ones with IP4=1 in the other LUT3. The non-registered output of multiplexer 403, which is effectively the output of the desired “4-input logic gate,” can be available at the outputs of multiplexers 408 and/or 409, OP1 and/or OP2, by setting S12 and/or S13, respectively. But if the registered version of the output of multiplexer 403 is desired, setting of S7 routes its output to the D flip-flop and from there setting of S10 and/or S15 will make the registered output available at OP1 and/or OP2, respectively. The very same arrangement creates a 4-input look-up table, a LUT4, as this arrangement makes 2⁴ memory bits available and addressable by IP1 through IP4. S17 and S18 switches must remain open for non-accumulating or non-bypassing. Furthermore, each LUT3 can be used separately to implement 1-, 2-, or 3-input logic gates, as each can provide 2³ bits of memory, which covers all possible combinations of up to 3 inputs.

The two LUT3s, 405 and 406, can be used in parallel if, for example, by setting S9 and S16 or S11 and S14. With such hard-wiring of the two multiplexers 408 and 409 one output port of the logic cell can be connected to the output of one LUT3 and the other output port to the other LUT3. If LUT3s are used separately, one of their outputs can be available in registered form by setting S5 or S8 of multiplexer 404. However, by setting S7 and controlling IP4, the user can continuously choose the output of either one of the LUT3s to be in registered form. Switches S17 and S18 must remain open. The above explanation enables a person of ordinary skill in the appropriate art to easily use either or both of the LUT3s as LUT2s.

Since a 1-bit full-adder is defined as a circuit which accepts two bits and an input carry and which produces a sum bit and an output carry bit, the logic cell can be configured to function in the same manner. First, the logic cell must be configured as two parallel and separate LUT3s with, for example, OP1 connected to the non-registered output of one LUT3 and OP2 connected to the non-registered output of the other LUT3. Additionally S0 and S2 must be set to have IP1, IP2, and IP3 as inputs to both LUT3s. With such arrangement IP1 and IP2 can represent the two bits to be added together and IP3 can represent the carry-in bit. With such configuration one LUT3 can store the single bit addition result of the 2³ possible combinations of IP1, IP2, and IP3, and the other LUT3 can produce the one bit carry-out of the 2³ possible combinations.

The other arrangement to implement a full-adder is again to configure the logic cell to function as two parallel and separate LUT3s but to set S1 and S4. With this arrangement IP1 can be one of the bits to be added, IP2 and IP3 both must be connected to the other bit to be added and Cᵢₙ will represent the carry-in bit. Here, the look-up table 405 stores the carry-out bit, which can be read at Cₒᵤₜ, and the look-up table 406 stores the single bit addition result, which can be read at OP1 or OP2. The description of a 1-bit full-adder and the feedback provisions of the logic cells enable those persons with ordinary skill in the relevant art to also arrange an accumulator of any bit-length.

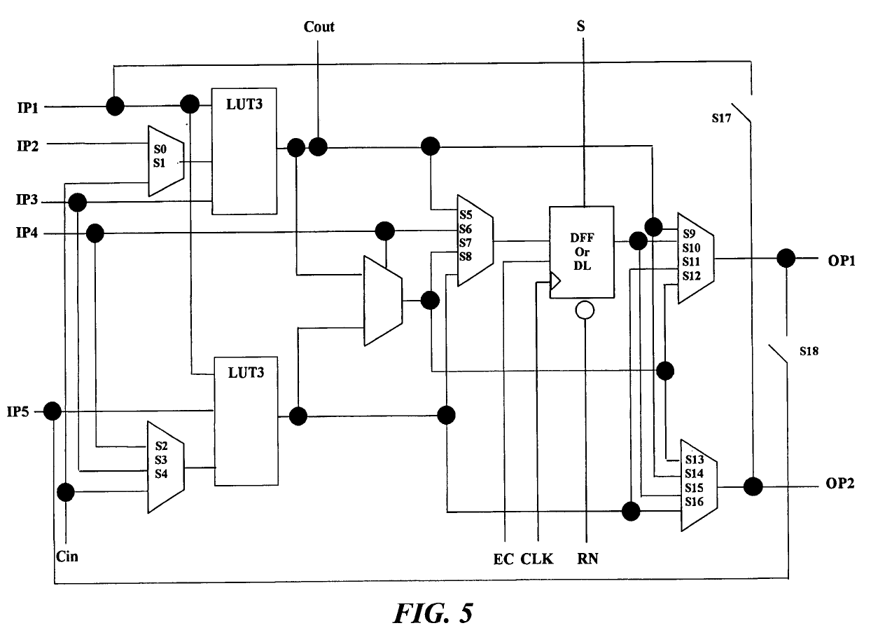

FIG. 5 is a schematic circuit diagram of a 5-input 2-output logic cell in accordance with another embodiment of the present invention. This logic cell has all the features of the logic cell of FIG. 4, in addition to implementing one LUT2 and one LUT3, in parallel or in series, with independent inputs.

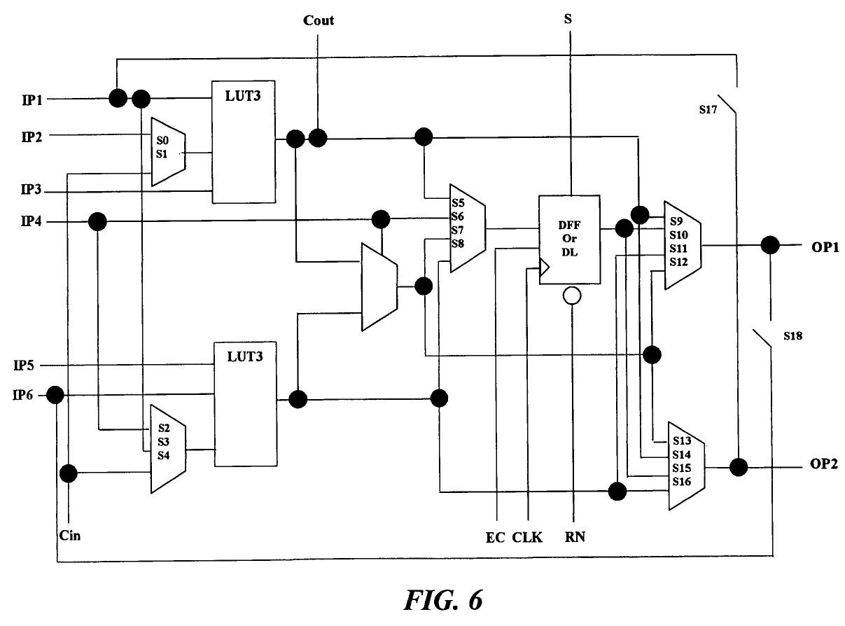

FIG. 6 is a schematic circuit diagram of a 6-input 2-output logic cell in accordance with another embodiment of the present invention. This logic cell has all the features of the logic cell of FIG. 4, in addition to implementing two LUT3s, in parallel or in series, with independent inputs.

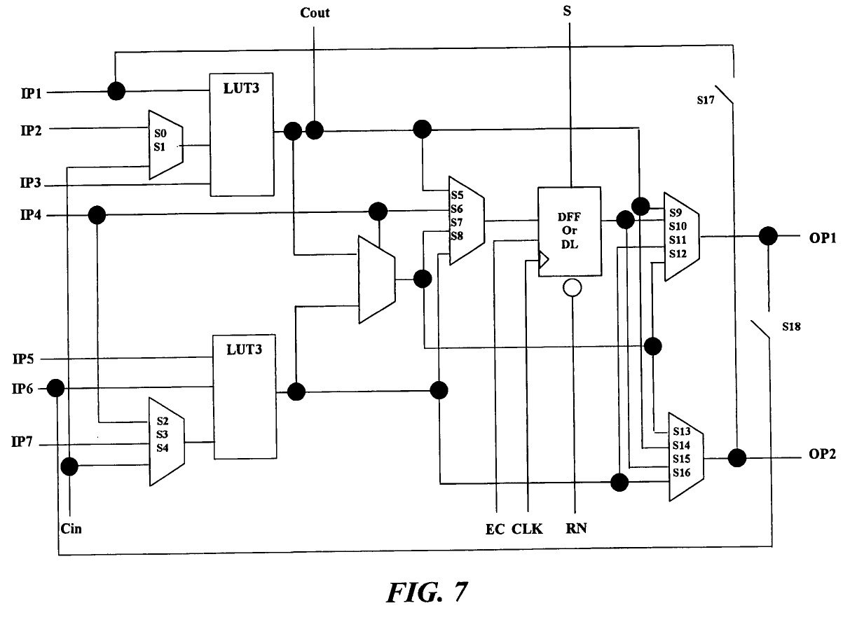

FIG. 7 is a schematic circuit diagram of a 7-input 2-output logic cell in accordance with another embodiment of the present invention. This logic cell has all the features of the logic cell of FIG. 4, in addition to implementing two LUT3s, in parallel or in series, with independent inputs.

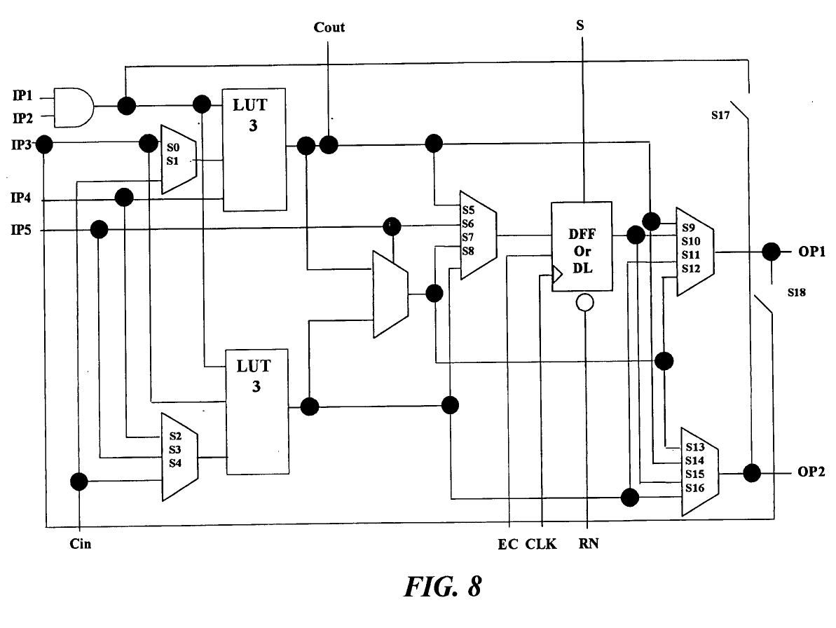

FIG. 8 is a schematic circuit diagram of a 5-input 2-output logic cell in accordance with another embodiment of the present invention. For additional functionality this cell employs a 2-input AND gate. The structure of the logic cell in FIG. 8 is also representative of similar logic cells with 6 and 7 inputs. This logic cell and its 6- and 7-input counterparts have all the features of the above mentioned 5-, 6-, and 7-input logic cells, respectively, in addition to performing multiplication as a result of their dedicated internal AND gate.

The preferred and several alternate embodiments have thus been described. After reading the foregoing specification, one of ordinary skill in the relevant art will be able to effect various changes, alterations, combinations, and substitutions of equivalents without departing from the broad concepts disclosed. It is therefore intended that the scope of the letters patent granted hereon be limited only by the definitions contained in the appended claims and equivalents thereof, and not by limitations of the embodiments described herein.

1. A logic cell, comprising:
3-input look-up tables, a plurality of cascading multiplexers at least one of which is a standard 2×1 multiplexer, a plurality of switches, and a register, wherein the switches can provide feedback paths from the outputs to the inputs or by-pass paths from the inputs to the outputs.

2. The logic cell of claim 1, wherein there are four to seven inputs and two outputs.

3. The logic cell of claim 1, wherein the registers are flip-flops.

4. The logic cell of claim 1, wherein switches are transfer (pass-gate) switches.

5. The logic cell of claim 1, wherein both registered and non-registered form of the outputs are available.

6. The logic cell of claim 1, wherein an additional dedicated AND gate is included to the logic cell for performing multiplication.

7. The logic cell of claim 1, wherein the logic cell can be configured and partitioned to perform logic functions of up to four inputs, and to operate as a 1-bit adder, an accumulator, an AOI/OAI, a 4-input look-up table, two 3-input look-up tables, two 2-input look-up tables, or one 2-input and one 3-input look-up table, where the look-up tables can separately operate in parallel and both the registered and the non-registered form of the logic cell outputs are available.

8. A field programmable gate array logic cell, comprising:
3-input look-up tables, multiplexers, switches, and flip-flops, wherein the switches may provide feedback paths from the outputs to the inputs or by-pass paths from the inputs to the outputs, and wherein at least one multiplexer is an ordinary multiplexer and the rest are hard-wired.

9. The logic cell of claim 8, wherein there are four to seven inputs and two outputs.

10. The logic cell of claim 8, wherein the flip-flop is a D flip-flop.

11. The logic cell of claim 8, wherein switches are transfer (pass-gate) switches.

12. The logic cell of claim 8, wherein an additional dedicated AND gate is included to the logic cell for performing multiplication.

13. The logic cell of claim 8, wherein both registered and non-registered form of the outputs are available.

14. The logic cell of claim 8, wherein the logic cell can be configured and partitioned to perform logic functions of up to four inputs, and to operate as a 1-bit adder, an accumulator, an AOI/OAI, a 4-input look-up table, two 3-input look-up tables, two 2-input look-up tables, or one 2-input and one 3-input look-up table, where the look-up tables can separately operate in parallel and both the registered and the non-registered form of the logic cell outputs are available.

15. A field programmable gate array logic cell, comprising:
two 3-input look-up tables, one standard 2×1 multiplexer, five hard-wired multiplexers, programmable transfer switches, a D flip-flop, wherein the switches may provide feedback paths from the outputs to the inputs or by-pass paths from the inputs to the outputs.

16. The logic cell of claim 15, wherein there are four to seven inputs and two outputs.

17. The logic cell of claim 15, wherein an additional dedicated AND gate is included to the logic cell for performing multiplication.

18. The logic cell of claim 15, wherein both registered and non-registered form of the outputs are available.

19. The logic cell of claim 15, wherein the logic cell can be configured and partitioned to perform logic functions of up to four inputs, and to operate as a 1-bit adder, an accumulator, an AOI/OAI, a 4-input look-up table, two 3-input look-up tables, two 2-input look-up tables, or one 2-input and one 3-input look-up table, where the look-up tables can separately operate in parallel and both the registered and the non-registered form of the logic cell outputs are available.

20. A field programmable gate array logic cell, comprising:
two 3-input look-up tables, one standard multiplexer, five hard-wired multiplexers, programmable transfer switches, a D flip-flop, and an AND gate, wherein the switches may provide feedback paths from the outputs to the inputs or by-pass paths from the inputs to the outputs.

21. The logic cell of claim 20, wherein there are four to seven inputs and two outputs.

22. The logic cell of claim 20, wherein both the registered and non-registered form of the outputs are available.

23. The logic cell of claim 20, wherein the logic cell can be configured and partitioned to perform multiplication and logic functions of up to four inputs, and to operate as a 1-bit adder, an accumulator, an AOI/OAI, a 4-input look-up table, two 3-input look-up tables, two 2-input look-up tables, or one 2-input and one 3-input look-up table, where the look-up tables can separately operate in parallel and both the registered and the non-registered form of the logic cell outputs are available.

24. A logic cell, comprising:
look-up tables, cascading multiplexers, switches, a register, and an AND gate, wherein the switches may provide feedback paths from the outputs to the inputs or by-pass paths from the inputs to the outputs, and wherein at least one multiplexer is an ordinary multiplexer and the rest are hard-wired, and wherein the logic cell can be configured and partitioned to perform multiplication and logic functions of up to four inputs, and to operate as a 1-bit adder, an accumulator, an AOI/OAI, a 4-input look-up table, two 3-input look-up tables, two 2-input look-up tables, or one 2-input and one 3-input look-up table, where the look-up tables can separately operate in parallel and both the registered and the non-registered form of the logic cell outputs are available.

25. The logic cell of claim 24, wherein there are four to seven inputs and two outputs.

26. The logic cell of claim 24, wherein the registers are D flip-flops.

27. The logic cell of claim 24, wherein switches are transfer (pass-gate) switches.

28. A field programmable gate array logic cell means with 4 to 7 inputs and 2 outputs for performing, among other functions, logic functions of up to four inputs, and for operating as a 1-bit adder, an accumulator, an AOI/OAI, 2- or 3- or 4-input look-up tables, where the look-up tables can separately operate in parallel and in series and both the registered and the non-registered form of the logic cell outputs are available, and wherein the switches may provide feedback paths from the outputs to the inputs or by-pass paths from the inputs to the outputs, and at least one multiplexer is an ordinary multiplexer and the rest are hard-wired.

29. A field programmable gate array logic cell means with 5 to 7 inputs and 2 outputs for performing, among other functions, logic functions of up to four inputs and multiplication, and for operating as a 1-bit adder, an accumulator, an AOI/OAI, 2- or 3- or 4-input look-up tables, where the look-up tables can separately operate in parallel and in series and both, the registered and the non-registered, forms of the logic cell outputs are available, and wherein the switches may provide feedback paths from the outputs to the inputs or by-pass paths from the inputs to the outputs, and at least one multiplexer is an ordinary multiplexer and the rest are hard-wired.
